(19) United States
(12) Patent Application Publication
(10) Pub. No.: US 2016/0170126 A1
(43) Pub. Date: Jun. 16, 2016

(54) Light Source Device, Lighting Device and Liquid Crystal Display Device

(71) Applicant: SAKAI DISPLAY PRODUCTS CORPORATION, Sakai-shi, Osaka (JP)

(72) Inventor: Tomoo Sasaki, Sakai-shi, Osaka (JP)

(21) Appl. No.: 14/908,277

(22) PCT Filed: Jul. 11, 2014
(86) PCT No.: PCT/JP2014/068624

§ 371 Date: Jan. 28, 2016

(30) Foreign Application Priority Data
Jul. 30, 2013 (JP) 2013-158084

(51) Int. Cl. F21V 8/00; H01L 33/58; H01L 33/54; H01L 33/48; H01L 33/60

(52) U.S. Cl. CPC G02B 6/0031; G02B 6/0025; G02B 6/0056; H01L 33/483; H01L 33/60; H01L 33/54; H01L 33/58

(57) ABSTRACT

Provided is a light source device, a lighting device and a liquid crystal display device, capable of improving the incidence efficiency to an optical member.

In a light source device 40 emitting light from a light source 53 mounted on an inner bottom surface of a container 52 toward a ceiling surface of the container 52, the container 52 comprises a bottom wall 521, a reflection side wall 522 arranged around the bottom wall 521 and having an inner surface bulging out, for reflecting light from the light source 53, and a reflection ceiling wall 523 arranged protrudingly from a ceiling side edge of the reflection side wall 522 toward an inner circumference, for reflecting light from the light source 53 to the inside of the container 52, the reflection ceiling wall having an opening 5231 for emitting the reflected light.

### CROSS-REFERENCE TO RELATED APPLICATIONS

This application is the national phase under 35 U.S.C. §371 of PCT International Application No. PCT/JP2014/068624 which has an International filing date of Jul. 11, 2014 and designated the United States of America.

### FIELD

The present application relates to a light source device, a lighting device and a liquid crystal display device.

### BACKGROUND

A light source device that emits light from a light source to a certain range of angle is known (see International Publication WO 2010/029872, for example). In the light source device according to International Publication WO 2010/029872 a plate-shaped conductor for supplying electric current to the light source is arranged at the side opposite to the light emission side of the light source, and a silver-plated layer with high reflectivity is formed on a surface of the conductor. In the light source device according to International Publication WO 2010/029872, luminous efficiency is improved by the silver-plated layer reflecting the light from the light source. The light source device according to International Publication WO 2010/029872 can be utilized for a direct type or edge light type backlight in a liquid crystal display device.

### SUMMARY

In a liquid crystal display device that employs an edge light type backlight, a light source device is arranged with a certain distance from one side surface of a light guide plate, in consideration of thermal expansion of the light guide plate. Therefore, when light is emitted from the light source device according to International Publication WO 2010/029872 to an optical member such as a light guide plate, some light is emitted to the outside of the optical member, according to the distance between the light source device and the optical member. Therefore, the incidence efficiency of the amount of the light entering the optical member to the amount of the light emitted from the light source device according to International Publication WO 2010/029872 not enough. It should be noted that the optical member also includes a diffusion plate for lighting, etc.

The present application is made in consideration of the above-described circumstances. The object of the present application is to provide a light source device, a lighting device and a liquid crystal display device that can improve the incidence efficiency to an optical member.

A light source device according to the present application emits light from a light source mounted on an inner bottom surface of a container toward a ceiling surface of the container. The container comprises a bottom wall, a reflection side wall arranged around the bottom wall and having an inner surface bulging out, for reflecting light from the light source, and a reflection ceiling wall arranged protrudingly from a ceiling side edge of the reflection side wall toward an inner circumference, for reflecting light from the light source to inside of the container, the reflection ceiling wall having an opening for emitting reflected light.

The light source device according to the present application comprises a translucent resin filling inside the container and covering an exterior of the container, and a reflection plate being smaller than the opening of the reflection ceiling wall and sealed with the translucent resin near the center of the opening, for reflecting light from an inside and an outside of the container.

In the light source device according to the present application, one or a plurality of prisms are formed on a surface of the translucent resin through which light emitted from the opening of the reflection ceiling wall passes.

A lighting device according to the present application comprises the light source device described above, and a light guide plate having one side surface arranged to face the light source device, for diffusing light emitted from the light source device to inside of the light guide plate through the one side surface to emit the light from one surface of the light guide plate. On one end including the one side surface, the light guide plate has a polarized light splitting element for splitting the light emitted from the light source device into P-polarized light and S-polarized light, transmitting the P-polarized light through the polarized light splitting element and reflecting the S-polarized light to an outside of the light guide plate.

A liquid crystal display device according to the present application comprises the lighting device described above and a liquid crystal panel for displaying an image using light emitted from one surface of the light guide plate of the lighting device.

The light source and so forth according to the present application improves the incidence efficiency to an optical member.

### BRIEF DESCRIPTION OF SEVERAL VIEWS OF DRAWINGS

FIG. 1 is a front perspective view of a liquid crystal panel module.

FIG. 2 is a lateral cross-sectional view of the lower end of the liquid crystal panel module.

FIG. 3 is a top view of an LED package.

FIG. 4 is a cross-sectional view of the LED package along the line IV-IV in FIG. 3.

FIG. 5 is a cross-sectional view of the LED package along the line V-V in FIG. 3.

FIG. 6 is an explanatory drawing to illustrate reflection of light from the LED on a reflection ceiling wall.

FIG. 7 is an explanatory drawing to illustrate entrance of light reflected at an inner surface of a container and a lower surface of a reflection plate.

FIG. 8 is an explanatory drawing to illustrate convergent light emitted from the LED package.

FIG. 9 is an explanatory drawing to illustrate narrowing down of the convergent light emitted from the LED package.

FIG. 10 is an explanatory drawing to illustrate that a reflection plate reflects return light from a light guide plate to the light guide plate.

FIG. 11 is an explanatory drawing to illustrate arrangement of two light source devices facing one side and another side of the light guide plate respectively.

FIG. 12 is an explanatory drawing to illustrate that the light which has entered the light guide plate from the light source device is reflected at another side surface of the light guide plate.

FIG. 13 is a lateral cross-sectional view of the light source device.

FIG. 14 is an explanatory drawing to illustrate behaviors of P-polarized light and S-polarized light on a surface of translucent resin.

FIG. 15 is an explanatory drawing to illustrate the light source device and the light guide plate with a polarizing beam splitter attached thereto.

### DETAILED DESCRIPTION

A liquid crystal display device according to one exemplified embodiment of the present application includes a television receiver, an electronic blackboard, a display device that is used while being connected with a tuner, a display device that is used while being connected with a desktop type computer, and a display device that is used for a digital signage. In addition, the liquid crystal display device according one exemplified embodiment of the present application includes a display device that is used in a tablet type computer, a personal digital assistant (PDA) or a cellular phone. As an example of liquid crystal display devices, a liquid crystal panel module that includes a liquid crystal panel and a backlight (lighting device) will be described hereinafter, with reference to the drawings related to the embodiments thereof.

### Embodiment 1

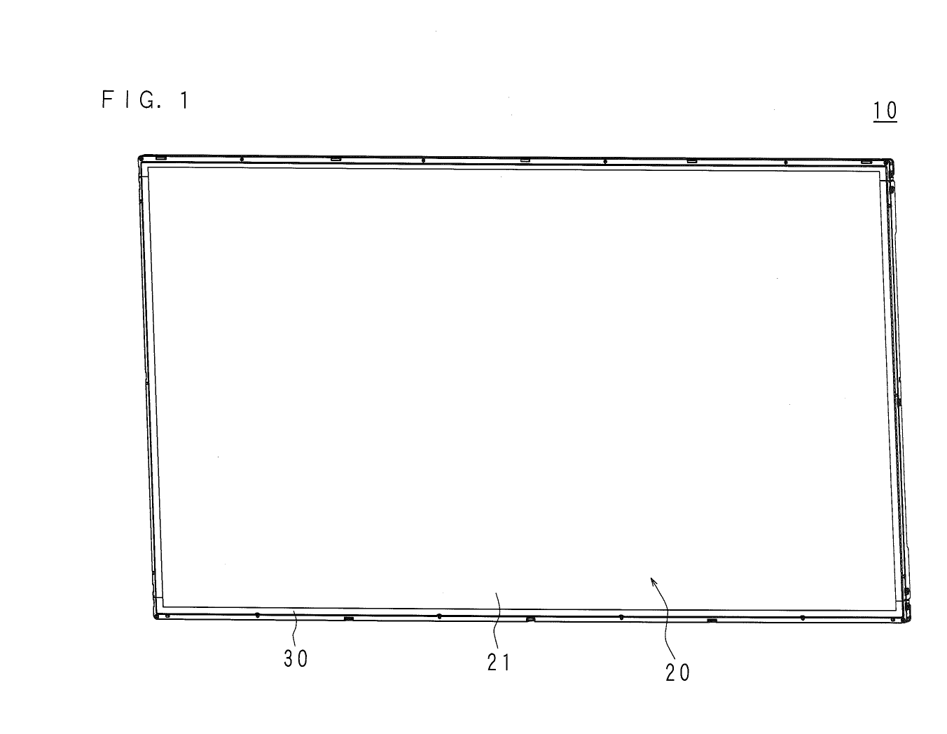

FIG. 1 is a front perspective view of a liquid crystal panel module 10. At this point, when a viewer confronts a screen 21 on which the liquid crystal panel module 10 in a standing posture displays an image, the viewer side seen from the screen 21 is referred to as an anterior side or a front side and the opposite side is referred to as a rear side or a back side. The liquid crystal panel module 10 and the screen 21 have a laterally long rectangular shape. As seen from the viewer facing the screen 21, the right side in the longitudinal direction of the screen 21 is referred to as the right side of the liquid crystal panel module 10, and the left side in the longitudinal direction of the screen 21 is referred to as the left side of the liquid crystal panel module 10. The upper side in the shorter length direction of the screen 21 is referred to as the upper side of the liquid crystal panel module 10, and the lower side in the shorter length direction of the screen 21 is referred to as the lower side of the liquid crystal panel module 10.

The liquid crystal panel module 10 includes a liquid crystal panel 20 and a frame body 30.

The liquid crystal panel 20 has the screen 21 at the front side and displays an image on the screen 21.

The frame body 30 includes an upper frame, two side frames and a lower frame that are made of synthetic resin or aluminum, which form a rectangular frame shape seen from the front side when combined.

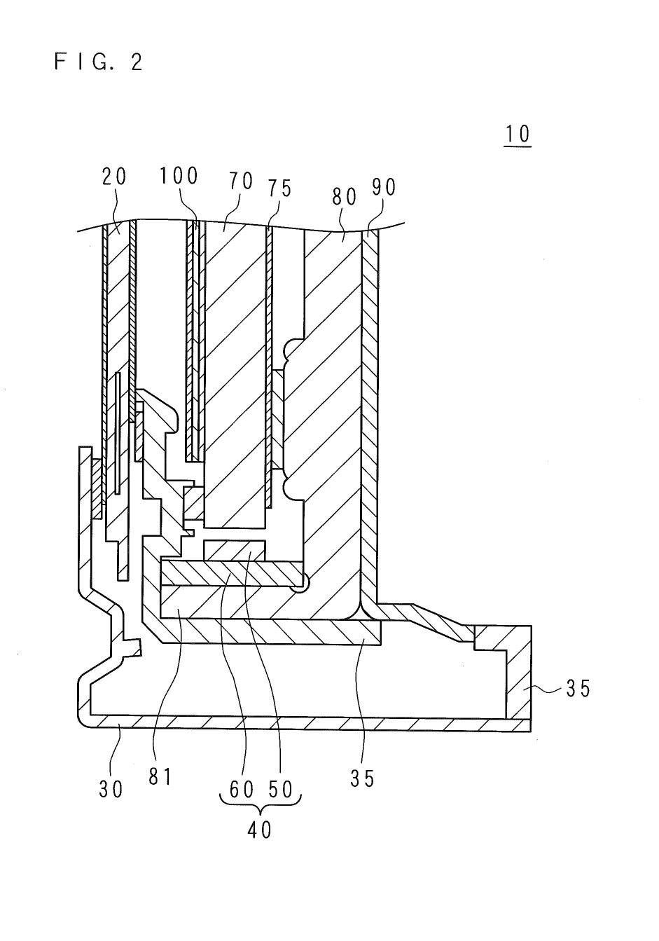

FIG. 2 is a lateral cross-sectional view of the lower end of the liquid crystal panel module 10. In FIG. 2, the left side of the drawing illustrates the front side of the liquid crystal panel module 10, and the right side of the drawing illustrates the rear side of the liquid crystal panel module 10.

The liquid crystal panel module 10 includes a light source device 40, a light guide plate 70, a reflection sheet 75, a heat dissipation plate 80, a backlight chassis 90 and an optical sheet 100. The light source device 40, the light guide plate 70, the reflection sheet 75, the heat dissipation plate 80 and the backlight chassis 90 compose a backlight of the liquid crystal panel module 10. The backlight of the liquid crystal panel module 10 employs an edge light type where the light source device 40 is arranged to face one side surface of the light guide plate 70.

The liquid crystal panel module 10 includes an inner frame 35. The inner frame 35 is a frame body that is made of synthetic resin and covers the peripheries of the backlight and the optical sheet 100. The frame body 30 covers the peripheries of the liquid crystal panel 20 and the inner frame 35 from the outer side, as well as the outer side of the screen 21 at the front side of the liquid crystal panel 20.

The light source device 40 is a component that emits light to one side surface at the lower side of the light guide plate 70. The light source device 40 includes an LED (Light Emitting Diode) package 50 and an LED substrate 60. The LED package 50 is a small piece where a light source is sealed with translucent resin. The LED substrate 60 is a rectangular aluminum plate elongated along the right-left direction. A plurality of LED packages 50 are mounted on the LED substrate 60 in an arrangement along the longitudinal direction of the LED substrate 60.

The light guide plate 70 is a rectangular plate, and is made of acryl or polycarbonate, for example.

The reflection sheet 75 is a thin film that has a substantial rectangular shape and is made of synthetic resin with high reflectivity. The size of the reflection sheet 75 is substantially equal to the rear surface of the light guide plate 70. The reflection sheet 75 is adhered to the rear surface of the light guide plate 70. The reflection sheet 75 reflects the light to the front side of the light guide plate in order to utilize efficiently the light that progresses toward the rear side inside the light guide plate 70.

The heat dissipation plate 80 is a rectangular plate-shaped member made of, for example, steel or aluminum. The longer side of the heat dissipation plate 80 is substantially parallel to the longitudinal direction of the LED substrate 60. The reflection sheet 75 is arranged at the front side of the hear dissipation plate 80 separately therefrom via a spacer. It should be noted that the reflection sheet 75 may abut on the front surface of the heat dissipation plate 80 without the spacer.

The heat dissipation plate 80 includes at the lower end a bent part 81 being bent toward the front side and has a lateral cross-sectional shape of L. The LED substrate 60 that has LED packages 50 mounted thereon is adhered to the upper surface of the bent part 81 with, for example, double-sided tape. The heat dissipation plate 80 has a function to dissipate the heat from the light source device 40 to the outside of the liquid crystal panel module 10.

The backlight chassis 90 is a rectangular parallel-piped box for holding the light guide plate 70, the reflection plate 75, the heat dissipation plate 80 and the optical sheet 100. The backlight chassis 90 is made of steel or aluminum, for example.

It should be noted that the heat dissipation plate 80 may have an additional function of the backlight chassis 90.

The optical sheet 100 is a substantially rectangular thin film. The size of the optical sheet 100 is substantially equal to the size of the light guide plate 70 or the liquid crystal panel 20. The optical sheet 100 includes a diffusion sheet, a prism sheet and a viewing angle enlargement sheet, for example. The diffusion sheet diffuses light. The prism sheet has a plurality of lenses arranged adjacent to each other and controls the progressing direction of light. The viewing angle enlargement sheet enlarges the viewing angle to provide good display quality.

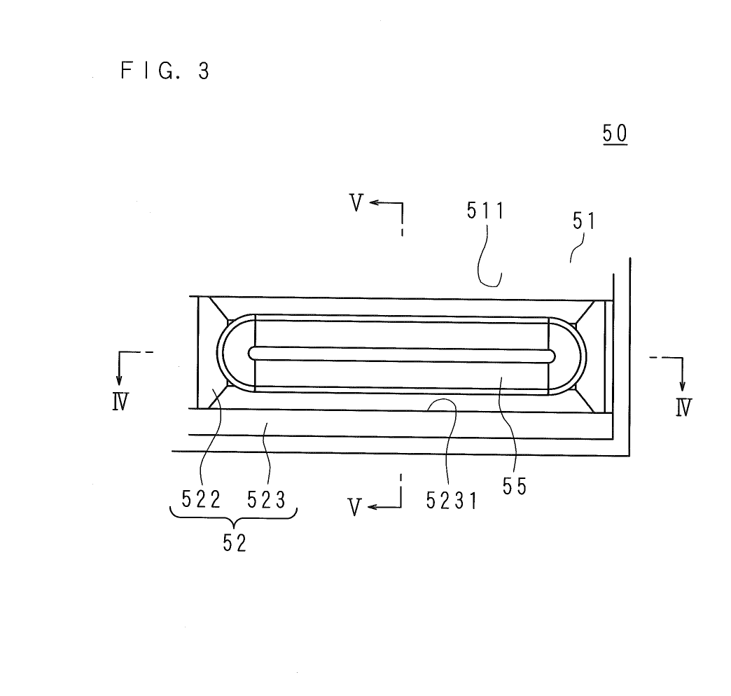

FIG. 3 is a top view of the LED package 50.

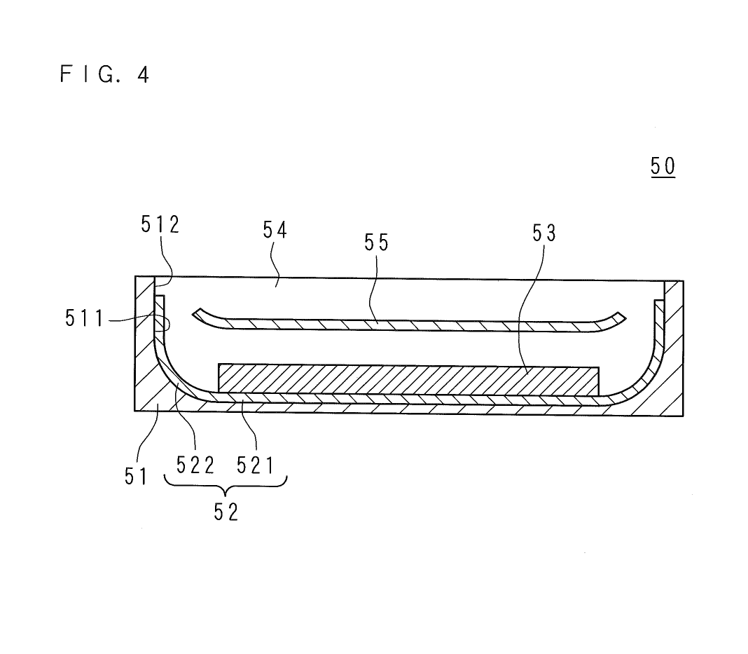

FIG. 4 is a cross-sectional view of the LED package 50 along the line IV-IV in FIG. 3.

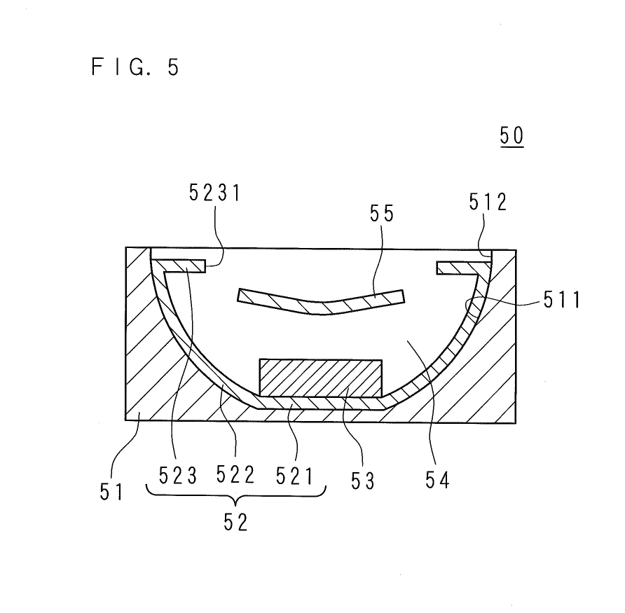

FIG. 5 is a cross-sectional view of the LED package 50 along the line V-V in FIG. 3.

The LED package 50 has a rectangular parallel-piped shape elongated along the right-left direction. The LED package 50 includes a frame 51, a container 52, an LED 53, translucent resin 54 and a reflection plate 55.

The frame 51 is a rectangular parallel-piped box body elongated along the right-left direction, and made of ceramics or resin. Inside the frame 51, a ship bottom shaped recess 511 is provided. The upper surface of the frame 51 has a rectangular opening, which forms a frame opening 512.

The container 52 is a copper reflector mounted on the recess 511 of the frame 51, which serves as a mold for the container 52. The container 52 has a ship bottom shape elongated along the right-left direction. The inner surface of the container 52 is silver-plated. It should be noted that the container 52 may be made of white ceramics with high reflectivity.

The container 52 includes a bottom wall 521, a reflection side wall 522 and a reflection ceiling wall 523.

The bottom wall 521 is a rectangular plate elongated along the right-left direction. There is, for example, one LED 53 as a light source, which is mounted on the inner surface of the bottom wall 521.

The reflection side wall 522 is a wall provided to be elongated upward from the entire periphery of the bottom wall 521 along the inner surface of the frame 51. The upper end of the reflection side wall 522 is positioned below the frame opening 512 of the frame 51. In the cross-sectional view in FIG. 5, the reflection side wall 522 has an arc shape or elliptical arc shape bending outward protrudingly.

There are two reflection ceiling walls 523, each of which is provided to protrude toward the inner circumference from the front and rear end portions of the reflection side wall 522 respectively. As illustrated in FIG. 3 and FIG. 5, the two reflection ceiling walls 523 are provided to be substantially perpendicular to the reflection side wall 522 from the front and rear ends respectively, of the reflection side wall 522, elongated along the right-left direction. In the LED package 50, the reflection ceiling wall 523 looks similar to a half-opened ceiling of a domed hall with the ceiling. The reflection ceiling wall 523 has a function to reflect the light from the LED 53 to the inside of the container 52.

It should be noted that the reflection ceiling wall 523 may be provided at the end portion of the reflection side wall 522 in a picture frame shape along the inner circumference of the end portion.

The region inside each of the end portions of the two reflection ceiling walls 523 forms a rectangular opening 5231. The area of the opening 5231 is smaller than the frame opening 512 by the area of the reflection ceiling wall 523.

The translucent resin 54 is silicon resin, epoxy resin, acrylic resin, norbornene resin, or the like with a high light transmission rate. The translucent resin 54 is filled into the inside of the container 52. The translucent resin 54 is also filled into the space from the opening 5231 to the frame opening 512.

The reflection plate 55 is a tray shaped copper plate having an inward (downward) concave and being elongated along the right-left direction. In FIG. 5, the reflection plate 55 is sealed with the translucent resin 54 at the position closer to the opening 5231 between the center point of the opening 5231 of the container 52 and the LED 53. Alternatively, the reflection plate 55 may be sealed with the translucent resin 54 at the position of the center point of the opening 5231 or the position slightly above the center point of the opening 5231.

It should be noted that the translucent resin 54 filled into the space above the opening 5231 is not necessary if the reflection plate 55 is sealed with the translucent resin 54 at the position illustrated in FIG. 5.

The upper surface and the lower surface of the reflection plate 55 are silver-plated. It should be noted that the reflection plate 55 may be made of white ceramics with high reflectivity.

The reflection plate 55 reflects the light from the outside of the container 52 to the outside thereof and reflects the light from the inside of the container 52 to the inside thereof. In more detail, the reflection plate 55 has a function to reflect to the light guide plate 70 the light directed from the light guide plate 70 to the light source device 40 (the returned light), and a function to reflect to the inside of the container 52 the light from the LED 53 and the light emitted from the LED 53 and reflected on the inner surface of the container 52. Because the reflection plate 55 is positioned near the center point of the opening 5231 of the container 52, an interval is formed between the end portion of the reflection ceiling wall 523 and the periphery of the reflection plate 55. The light originally emitted from the LED 53 is emitted from the interval toward the one side surface of the light guide plate 70.

The operation of the backlight of the liquid crystal panel module 10 will be described below.

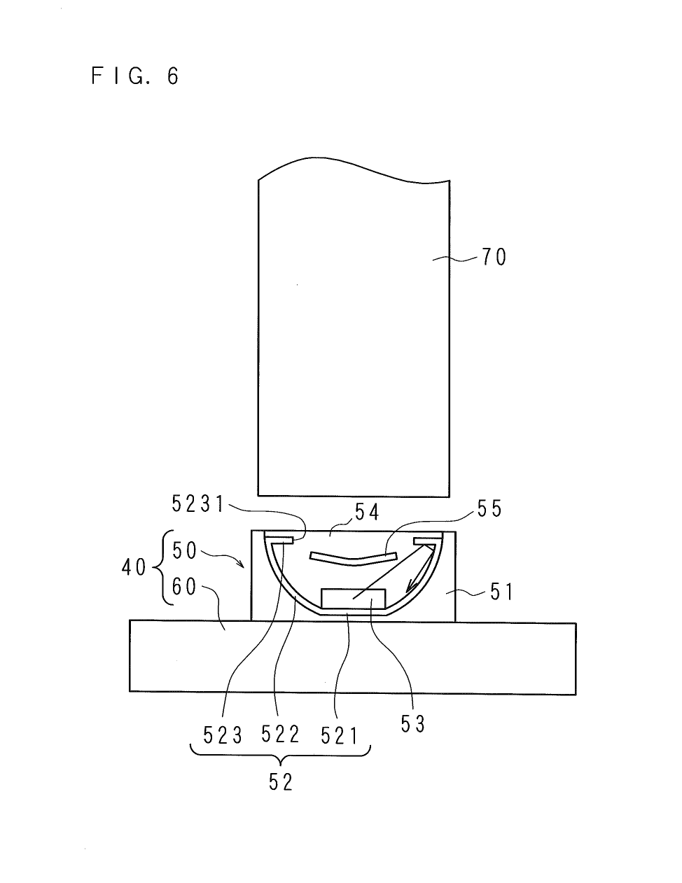

FIG. 6 is an explanatory drawing to illustrate reflection of light from the LED 53 on the reflection ceiling wall 523. In FIG. 6, the polygonal line including an arrow head represents a path of the light from the LED 53. The light is emitted from the LED 53 toward the ceiling wall side of the container 52 at various angles.

If there is no reflection ceiling wall 523, the light emitted at larger angle with respect to the normal direction of the LED substrate 60 leaks more to the space outside the one side surface of the light guide plate 70. The light leaking to the space outside the one side surface of the light guide plate 70 is out of use for displaying an image on the liquid crystal panel 20. Therefore, brightness at the screen 21 decreases by the amount of the light leaked to the space outside the one side surface of the light guide plate 70.

The reflection ceiling wall 523 is provided at the position where the light emitted from the LED 53 at an angle toward an outer side of the one side surface of the light guide plate 70. Therefore, the light emitted from the LED 53 at the angle toward the outer side of the one side surface of the light guide plate 70 is reflected at the reflection ceiling wall 523 to be directed to the reflection side wall 522 of the container 52. The light directed to the reflection side wall 522 of the container 52 is reflected on the inner surface of the reflection side wall 522.

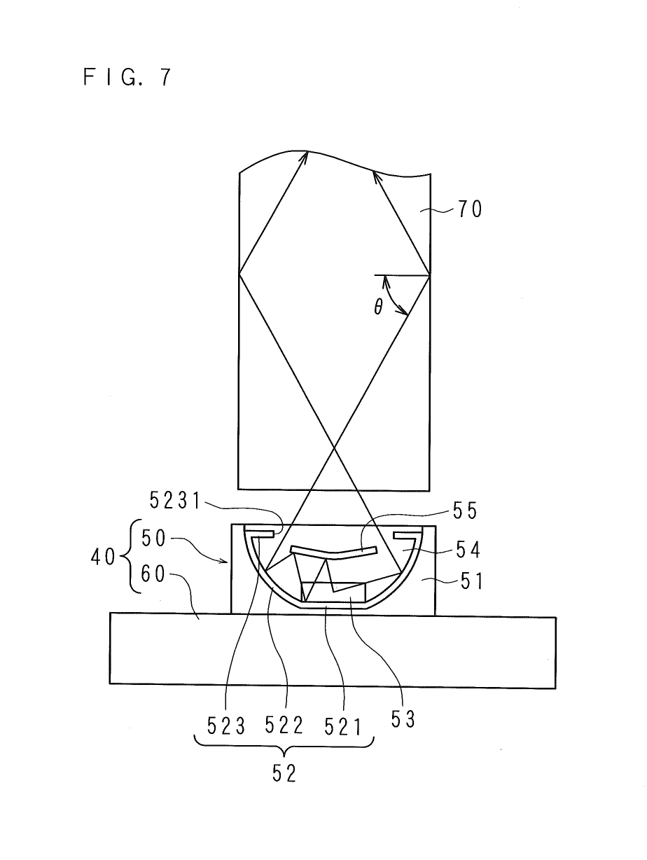

FIG. 7 is an explanatory drawing to illustrate entrance of light from the LED 35 reflected at the inner surface of the container 52 and the lower surface of the reflection plate 55. In FIG. 7, the polygonal lines including arrow heads represent paths of the light from the LED 53. In FIG. 7, 0 represents the angle at which light is totally reflected on the inner surface of the light guide plate 70. For example, in the case that the light guide plate 70 is made of acryl, θ≧42 degrees is satisfied.

A part of light reflected on the reflection ceiling wall 523 and then reflected on the inner surface of the reflection side wall 522 is directed toward the one side surface of the light guide plate 70 from the interval formed between the end portion of the reflection ceiling wall 523 and the periphery of the reflection plate 55. In other words, the light emitted from the LED 53 at the angle toward the outer side of the one side surface of the light guide plate 70 is recycled to display an image on the liquid crystal panel 20. In addition, a part of the light reflected on the inner surface of the reflection side wall 522 is reflected repeatedly on the lower surface of the reflection plate 55 and the inner surface of the container 52, and finally is directed toward the one side surface of the light guide plate 70 from the interval formed between the end portion of the reflection ceiling wall 523 and the periphery of the reflection plate 55.

The light reflected on the reflection side wall 522 finally becomes the emitted light which passes through the interval formed between the end portion of the reflection ceiling wall 523 and the periphery of the reflection plate 55. The incident angle of the light on the light guide plate 70 is determined so that this emitted light is totally reflected on the inner surface of the light guide plate 70. In addition, the incident angle on the light guide plate 70 is adjusted by the focal position corresponding to the inner surface of the reflection side wall 522. The focal position is dependent on the shape or the curvature of the inner surface of the reflection side wall 522 which has an arc or elliptical arc lateral cross-sectional shape (an elliptical arc which has a focus is desirable, but an arc is approximately equal). In other words, the incident angle on the light guide plate 70 corresponds to the shape of the inner surface of the reflection side wall 522.

Because the container 52 has an elongated shape along the right-left direction (direction vertical to the sheet of the drawing in FIG. 7), the focus is positioned on the plane that passes through the center of the light guide plate 70 and is substantially parallel with the one surface of the light guide plate 70 that irradiates the liquid crystal panel 20 with light.

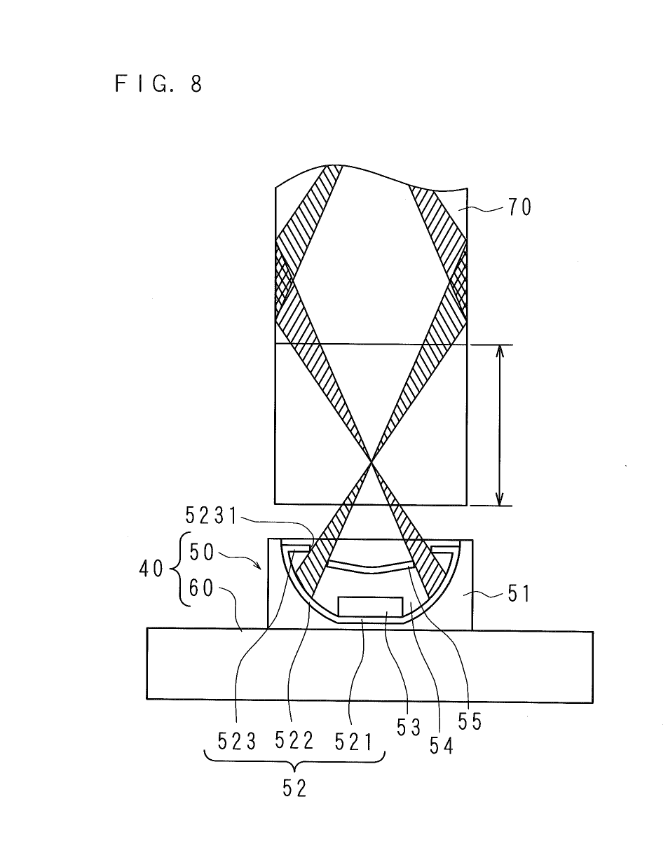

FIG. 8 is an explanatory drawing to illustrate convergent light emitted from the LED package 50. In FIG. 8, the hatched part represents the convergent light. Additionally in FIG. 8, the line segment with arrow heads on its both ends represents fluctuation in the position of the one side surface of the light guide plate 70 due to thermal expansion or contraction thereof.

The light from the LED 53 is reflected on the reflection ceiling wall 523 and the reflection side wall 522 of the container 52 and on the reflection plate 55, and is finally converged to a flux of light that passes through the interval formed between the end portion of the reflection ceiling wall 523 and the periphery of the reflection plate 55. The shape of the inner surface of the reflection side wall 522 is adjusted to adjust the incident angle of the convergent light to the light guide plate 70, so that all of the convergent light enters the one side surface of the light guide plate 70 even when the light guide plate 70 before expansion is positioned farthest from the light source device 40.

The width of the convergent light may also be a factor of making all the convergent light enter the one side surface of the light guide plate 70 even when the position of the light guide plate 70 is farthest from the light source device 40. The width of the convergent light varies depending on the shape of the inner surface of the reflection side wall 522. The width of the convergent light also varies depending on the size and the position of the reflection ceiling wall 523 and the reflection plate 55. Therefore, the shape of the inner surface of the reflection side wall 522 as well as the size and the position of the reflection ceiling wall 523 and the reflection plate 55 are adjusted to adjust the width of the convergent light directed to the light guide plate 70, so that all of the convergent light enters the one side surface of the light guide plate 70.

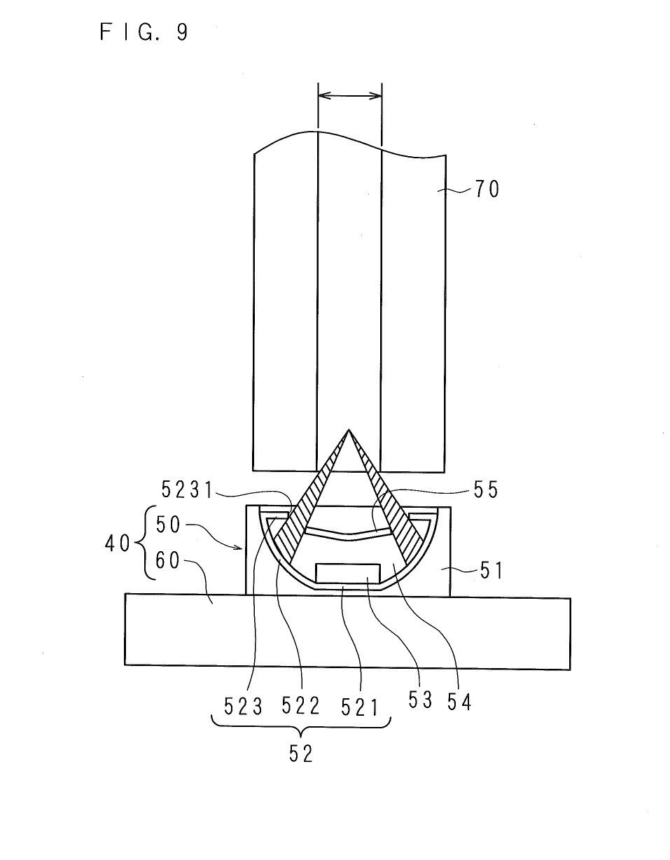

FIG. 9 is an explanatory drawing to illustrate narrowing down of the convergent light emitted from the LED package 50. In FIG. 9, the hatched part represents the convergent light. Additionally in FIG. 9, the line segment with arrow heads on its both ends represents an example of the diameter of the entering light spot. The diameter of the entering light spot is the width of the convergent light that is narrowed down and enters the one side surface of the light guide plate 70.

By adjusting the shape of the inner surface of the reflection side wall 522 as well as the size and the position of the reflection ceiling wall 523 and the reflection plate 55, the diameter of the entering light spot can be changed. If the diameter of the entering light spot is set to the size in FIG. 9, the thickness of the light guide plate 70 can be made thinner to the length of the line segment with arrow heads on its both ends. The manufacturing cost of the light guide plate 70 can thereby be reduced. In addition, the thinner light guide plate 70 contributes to the thinner liquid crystal panel module 10.

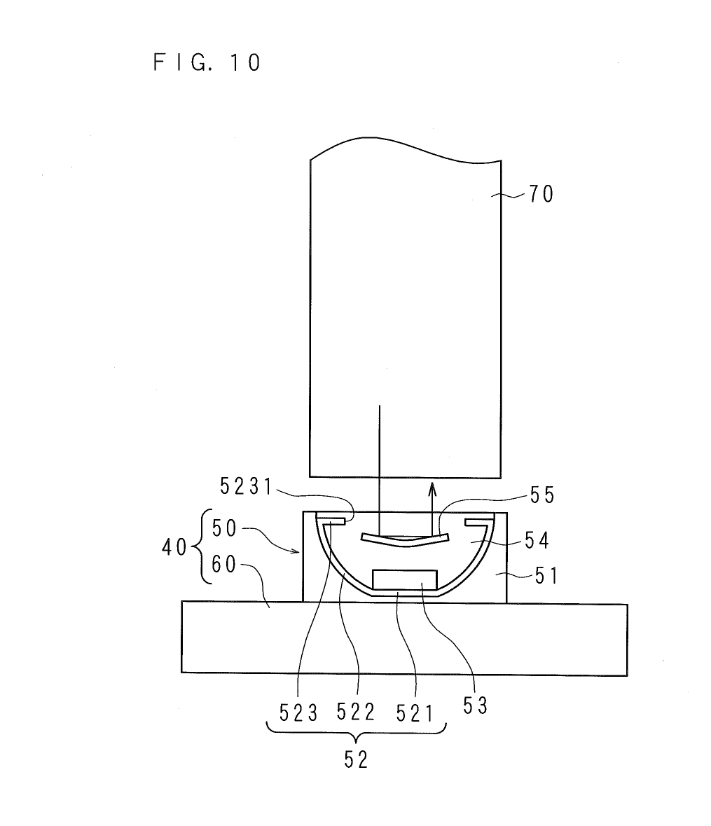

FIG. 10 is an explanatory drawing to illustrate that the reflection plate 55 reflects return light from the light guide plate 70 to the light guide plate 70. The return light illustrated here includes the light that is emitted from the LED package 50 and reflected on the one side surface of the light guide plate 70 to return to the LED package 50 and the light that is emitted from the LED package 50 and diffused at the inner surface of the light guide plate 70 to return to the LED package 50.

The reflection plate 55 reflects the return light from the light guide plate 70 to the light guide plate 70. The return light thereby reenters the light guide plate 70 to be recycled for displaying an image on the liquid crystal panel 20.

In the description above, the LED package 50 includes the frame 51. However, the LED package 50 may exclude the frame 51. The container 52 may be made thicker for a concern about a decline of the strength thereof without the frame 51.

In the description above, the LED package 50 includes the reflection plate 55. However, the LED package 50 may exclude the reflection plate 55. Because the LED package 50 includes at least the reflection ceiling wall 523, the LED package 50 recycles the light that would have leaked outside the light guide plate 70 in the conventional configuration so as to direct the light to the one side surface of the light guide plate 70. The incidence efficiency of the light source device 40 with respect to the light guide plate 70 is thereby improved, compared to the conventional configuration.

According to the light source device 40, the incidence efficiency to an optical member such as the light guide plate 70 can be improved.

The reflection ceiling wall 523 reflects the light emitted from the LED 53 at the angle toward the outer side of the light guide plate 70 to the inside of the container 52. The light reflected to the inside of the container 52 is finally directed to the one side surface of the light guide plate 70. The incidence efficiency of the light source device 40 with respect to the light guide plate 70 can thereby be improved.

The reflection plate 55 reflects the return light from the light guide plate 70 to the light guide plate 70. The reflection plate 55 also reflects the light from the LED 53 to the inside of the container 52. The light reflected to the inside of the container 52 is finally directed to the one side surface of the light guide plate 70. The incidence efficiency of the light source device 40 with respect to the light guide plate 70 can thereby be improved.

The light from the LED 53 is uniformized through the reflection on the inner surface of the container 52 and the lower surface of the reflection plate 55. Therefore, the backlight can decrease the brightness unevenness at the screen 21 on the liquid crystal panel 20.

By adjusting the incident angle on the light guide plate 70 in consideration of the thermal expansion thereof, the light from the light source device 40 can be totally reflected on the inner surface of the light guide plate 70 immediately after the incidence to the light guide plate 70. The light guide plate 70 can thereby emit uniform light from one surface thereof to the rear surface of the liquid crystal panel 20.

By adjusting the shape of the inner surface of the reflection side wall 522 as well as the size and the position of the reflection ceiling wall 523 and the reflection plate 55 to make the diameter the entering light spot smaller, the light guide plate 70 of the backlight can be replaced by a thinner one. The manufacturing cost of the light guide plate 70 can thereby be reduced.

(Variation 1)

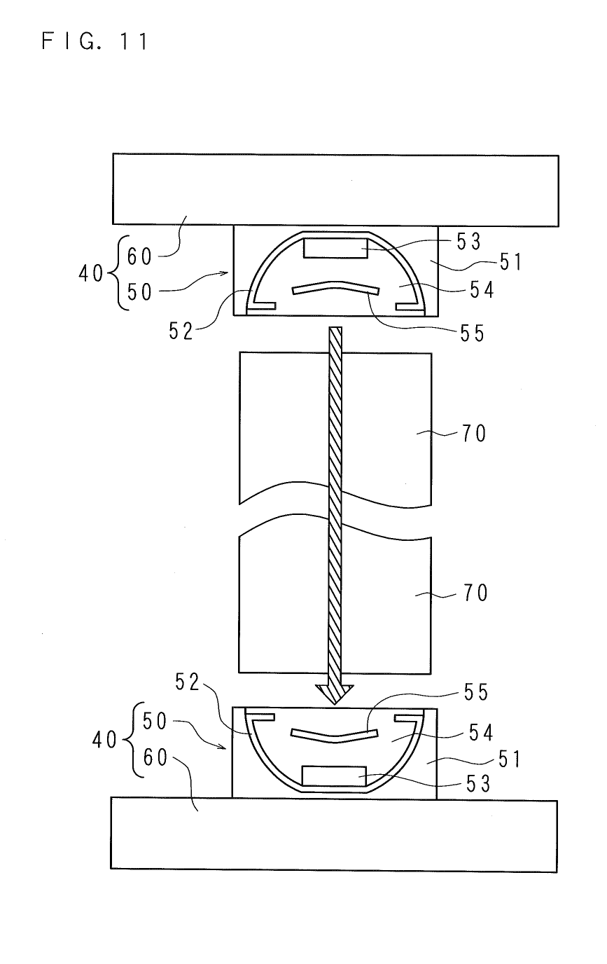

FIG. 11 is an explanatory drawing to illustrate arrangement of two light source devices 40 facing one side and another side of the light guide plate 70 respectively. In FIG. 11, the light source devices 40 which are arranged to face the upper side surface and the lower side surface of the light guide plate 70 respectively are illustrated one for each. Each of the light source devices 40 emits light to the upper side surface and the lower side surface of the light guide plate 70 respectively. In FIG. 11, the light emitted from the light source device 40 arranged to face the upper side surface of the light guide plate 70 is represented by one hatched arrow.

The backlight with the two light source devices 40 can emit brighter light to the rear surface of the liquid crystal panel 20. The brightness at the screen 21 on the liquid crystal panel 20 can thereby be increased.

The light emitted from one light source device 40 to the light guide plate 70 passes through the light guide plate 70 and reaches the other light source device 40. The light that has reached the other light source device 40 is reflected on the reflection plate 55 of the other light source device 40, for example, and thereby redirected to the light guide plate 70. In addition, the light that has reached the other light source device 40 enters the inside of the container 52 through the interval formed between the end portion of the reflection ceiling wall 523 and the periphery of the reflection plate 55 of the other light source device 40, for example, and is finally redirected to the light guide plate 70 through the interval. Therefore, the backlight can recycle the transmitted light of the light source device 40 passing through the light guide plate 70.

(Variation 2)

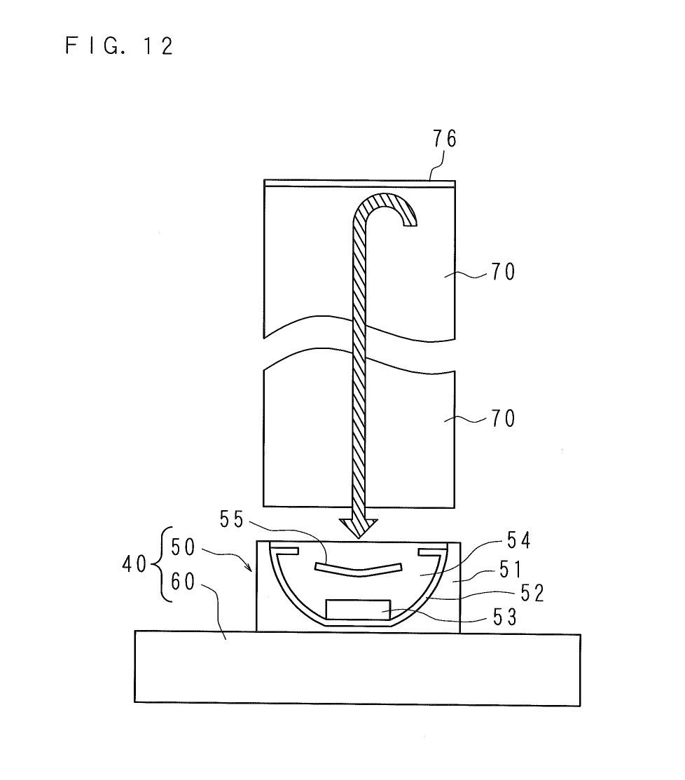

FIG. 12 is an explanatory drawing to illustrate that the light which has entered the light guide plate 70 from the light source device 40 is reflected at another side surface of the light guide plate 70. In FIG. 12, the light that has entered the light guide plate 70 from the light source device 40 and is reflected on another side surface of the light guide plate 70 is represented by one hatched arrow.

To another side surface opposite to one side surface of the light guide plate 70 arranged to face the light source device 40, a reflection sheet 76 is adhered. The reflection sheet 76 is a thin film made of synthetic resin with high reflectivity. The reflection sheet 76 reflects the light that has entered the light guide plate 70 from the light source device 40 and reaches the reflection sheet 76. The light reflected on the reflection sheet 76 passes through the light guide plate 70 and returns to the light source device 40. The light which has returned to the light source device 40 is redirected to the light guide plate 70, as in Variation 1. Therefore, the backlight can recycle the light which has been emitted from the light source device 40 and has reached another side surface of the light guide plate 70, without leaking the light to the outer side of the light guide plate 70.

### Embodiment 2

Embodiment 2 relates to an embodiment where a prism pattern is formed on a surface of the translucent resin 54 of the LED package 50 facing one side surface of the light guide plate 70.

In the following description about Embodiment 2, the components which are the same as those in Embodiment 1 are denoted by the same reference numerals and will not be described in detail.

The liquid crystal panel 20 includes liquid crystal and two front and rear polarizing filters holding the liquid crystal panel therebetween. The front polarizing filter transmits only S-polarized light and the rear polarizing filter transmits only P-polarized light. In the liquid crystal panel 20, compared to the backlight that emits both S-polarized light and P-polarized light to the liquid crystal panel 20, the backlight that emits only P-polarized light in the same total amount of light can increase the brightness at the screen 21 on the liquid crystal panel 20 by the amount of energy of the S-polarized light. Therefore, a prism pattern that transmits P-polarized light and reflects a part of S-polarized light is formed on the surface of the translucent resin 54 of the LED package 50. The part of the S-polarized light reflected is recycled through reflections on the container 52 and the reflection plate 55 of the LED package 50, and thereby redirected to the light guide plate 70.

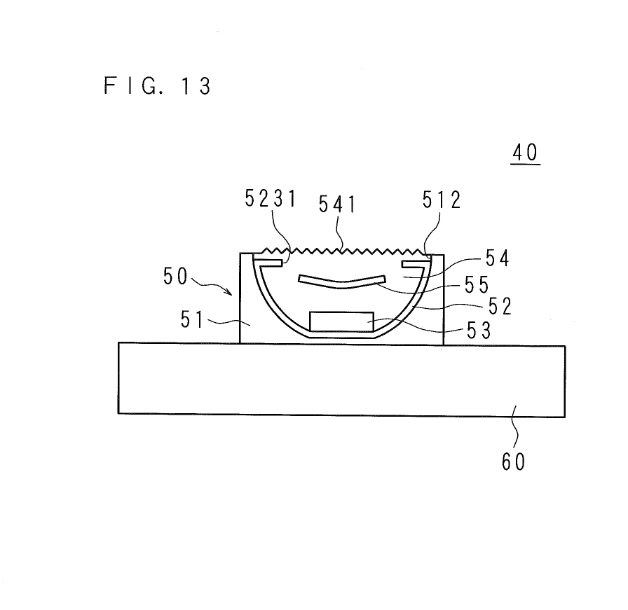

FIG. 13 is a lateral cross-sectional view of the light source device 40. A plurality of prisms 541 which have reverse V shaped lateral cross sections are formed on the surface of the translucent resin 54 filled from the opening 5231 to the frame opening 512. The plurality of prisms 541 are elongated along the right-left direction and substantially parallel with each other. Therefore, a prism pattern composed of substantially parallel the plurality of prisms 541 is formed on the surface of the translucent resin 54.

It should be noted that the prism pattern is not limited to the one composed of many linear prisms 541 disposed substantially in parallel. The prism pattern may be the one composed of the plurality of prisms that have different sizes and similar shapes (rectangular frame shaped prisms, for example) and are disposed concentrically. Alternatively, the prism pattern may be composed of one helical prism.

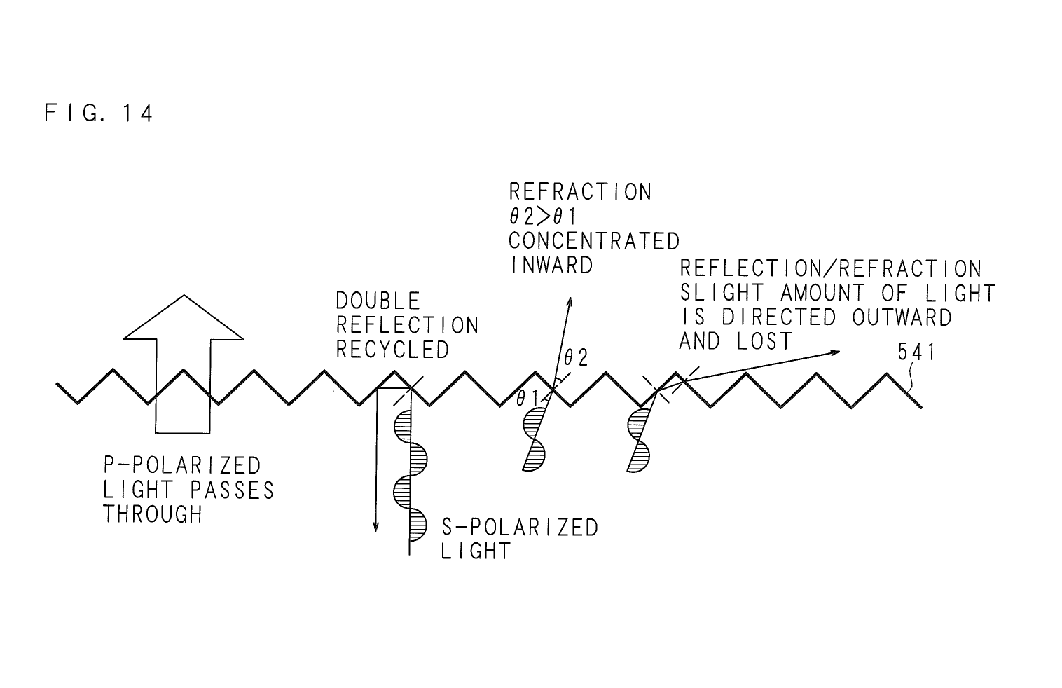

FIG. 14 is an explanatory drawing to illustrate behaviors of P-polarized light and S-polarized light on the surface of the translucent resin 54. The prism 541 illustrated in FIG. 14 is a right angle prism, for example. The light that has reached the surface of the prism 541 includes P-polarized light and S-polarized light. The prism 541 transmits the P-polarized light. On the other hand, the prism 541 reflects the S-polarized light twice to the LED package 50 which recycles the light as the return light. The prism 541 can also concentrate the light on the light guide plate 70 by refracting the S-polarized light inward, to increase the amount of light used for displaying an image. A slight amount of light is directed outward by reflection or refraction, and thereby lost.

In the description above, the prism pattern is formed on the surface of the translucent resin 54. However, an optical film with a prism pattern formed thereon may be alternatively adhered to the surface of the translucent resin 54.

According to the light source device 40, the brightness at the screen 21 on the liquid crystal panel 20 can be increased.

The light source device 40 converts a part of the S-polarized light that has reached the surface of the prism 541 at total reflection angle into P-polarized light and emits the converted light to the light guide plate 70. Therefore, a part of the S-polarized light which would be blocked by the polarizing filter of the liquid crystal panel 20 is converted into P-polarized light to be used for displaying an image on the liquid crystal panel 20. The brightness at the screen 21 on the liquid crystal panel 20 is increased by the amount of the converted light.

### Embodiment 3

Embodiment 3 relates to the embodiment where a polarizing beam splitter is mounted on one end of one side surface, of the light guide plate 70, which the light enters from the light source device 40. The polarizing beam splitter is an optical member that splits the incident light into P-polarized light and S-polarized light at a certain split ratio.

In the following description about Embodiment 3, the components which are the same as those in Embodiments 1 and 2 are denoted by the same reference numerals and will not be described in detail.

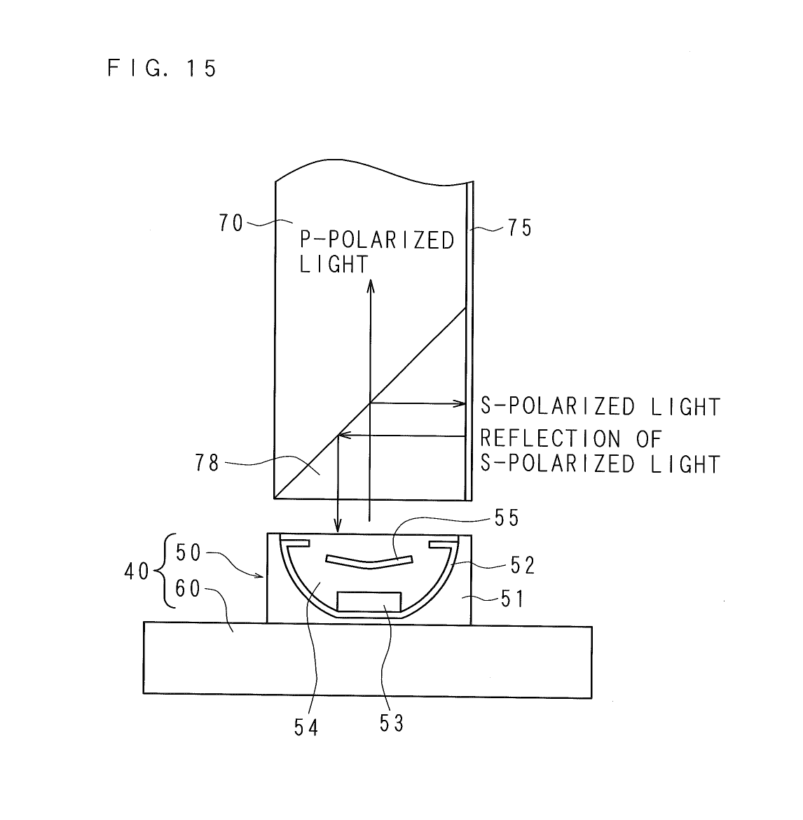

FIG. 15 is an explanatory drawing to illustrate the light source device 40 and the light guide plate 70 with a polarizing beam splitter 78 attached thereto. The polygonal lines with arrow heads represent the paths of light emitted from the light source device 40 inside the light guide plate 70 and the polarizing beam splitter 78.

The polarizing beam splitter 78 has a shape of a right angle prism. A slant side surface of the polarizing beam splitter 78 is adhered to a cut surface of the light guide plate 70 which is formed by diagonally cutting one end to be slanting from rear to front and from inside to outside. Therefore, the light from the light source device 40 enters one side surface of the polarizing beam splitter 78. The reflection sheet 75 is adhered to the rear surface of the light guide plate 70 and the rear surface of the polarizing beam splitter 78, over the seam between the light guide plate 70 and the polarizing beam splitter 78.

The light emitted from the light source device 40 enters the polarizing beam splitter 78 and reaches the boundary surface between the polarizing beam splitter 78 and the light guide plate 70. The incident light is split into P-polarized light and S-polarized light. The split P-polarized light passes through the boundary surface between the polarizing beam splitter 78 and the light guide plate 70 and enters the inside of the light guide plate 70 as it is. On the other hand, the split S-polarized light is reflected toward the rear (side) at the boundary surface between the polarizing beam splitter 78 and the light guide plate 70. The S-polarized light reflected toward the rear is reflected again toward the front by the reflection sheet 75. The S-polarized light reflected toward the front is reflected downward at the boundary surface between the polarizing beam splitter 78 and the light guide plate 70, and thereby returned to the light source device 40.

The S-polarized light returned to the light source device 40 is reflected on the upper surface of the reflection plate 55 and the inner surface of the container 52 and the lower surface of the reflection plate 55 to be directed to the polarizing beam splitter 78. The P-polarized light converted from the S-polarized light during such repeated reflecting back enters the polarized beam splitter 78 and then passes through the boundary surface between the polarizing beam splitter 78 and the light guide plate 70 to enter the inside of the light guide plate 70.

According to the backlight of the liquid crystal panel module 10, the brightness at the screen 21 on the liquid crystal panel 20 can be increased.

The polarizing beam splitter 78 that transmits only P-polarized light is adhered to the lower end of the light guide plate 70 which faces the light source device 40. The split S-polarized light is returned back to the light source device 40 to be recycled. The light source device 40 with less LEDs 53 can thereby provide enough brightness at the screen 21. Therefore, the electric power consumption can be reduced.

It should be understood that the embodiments disclosed herein are illustrative and non-restrictive in every respect. Since the scope of the present invention is defined by the appended claims rather than by the description preceding them, and all changes that fall within metes and bounds of the claims, or equivalence of such metes and bounds thereof are therefore intended to be embraced by the claims.

The technical features (components) described in the embodiments can be combined together, and the combination thereof can produce a new technical feature.

A light source device 40 emits light from a light source 53 mounted on an inner bottom surface of a container 52 toward a ceiling surface of the container 52. The container 52 comprises a bottom wall 521, a reflection side wall 522 arranged around the bottom wall 521 and having an inner surface bulging out, for reflecting light from the light source 53, and a reflection ceiling wall 523 arranged protrudingly from a ceiling side edge of the reflection side wall 522 toward an inner circumference, for reflecting light from the light source 53 to inside of the container 52, the reflection ceiling wall 523 having an opening for emitting reflected light.

According to the light source device 40, the incidence efficiency with respect to an optical member such as the light guide plate 70 can be improved.

The reflection ceiling wall 523 reflects the light emitted from the light source 53 at the angle toward the outer side of the optical member to the inside of the container 52. The light reflected to the inside of the container 52 is finally directed to the optical member. The incidence efficiency of the light source device 40 with respect to the optical member can thereby be improved.

The light source device 40 comprises a translucent resin 54 filling inside the container 52 and covering an exterior of the container 52, and a reflection plate 55 being smaller than the opening 5231 of the reflection ceiling wall 523 and sealed with the translucent resin 54 near the center of the opening 5231, for reflecting light from an inside and an outside of the container 52.

According to the light source device 40, the incidence efficiency to an optical member such as the light guide plate 70 can be improved.

The reflection plate 55 reflects the return light from the optical member to the optical member. The reflection plate 55 also reflects the light from the light source 53 to the inside of the container 52. The light reflected to the inside of the container 52 is finally directed to the optical member. The incidence efficiency of the light source device 40 with respect to the optical member can thereby be improved.

In the light source device 40, one or a plurality of prisms 541 are formed on a surface of the translucent resin 54 through which light emitted from the opening 5231 of the reflection ceiling wall 523 passes.

According to the light source device 40, the electric power consumption can be reduced.

The light source device 40 converts S-polarized light into P-polarized light in advance, because on the surface of the translucent resin 54, the light source device 40 has the prism 541 that transmits only P-polarized light. The light source device 40 can thereby supply enough amount of light using less light sources 53, compared to the case of not using the emitted S-polarized light. Therefore, the electric power consumption can be reduced.

A lighting device comprises the light source device 40, and a light guide plate 70 having one side surface arranged to face the light source device 40, for diffusing light emitted from the light source device 40 to inside of the light guide plate 70 through the one side surface to emit the light from one surface of the light guide plate 70. On one end including the one side surface, the light guide plate 70 has a polarized light splitting element 78 for splitting the light emitted from the light source device 40 into P-polarized light and S-polarized light, transmitting the P-polarized light through the polarized light splitting element 78 and reflecting the S-polarized light to an outside of the light guide plate 70.

According to the lighting device, the electric power consumption can be reduced.

The polarizing beam splitter 78 that transmits only P-polarized light is adhered to the lower end of the light guide plate 70 which faces the light source device 40. The split S-polarized light is returned back to the light source device 40 to be recycled. The lighting device with less LEDs 53 can thereby provide enough brightness at the screen 21. Therefore, the electric power consumption can be reduced.

A liquid crystal display device 210 comprises the lighting device and a liquid crystal panel 20 for displaying an image using light emitted from one surface of the light guide plate 70 of the lighting device.

According to the liquid crystal display device 210, the brightness at the screen 21 on the liquid crystal panel 20 can be increased.

The reflection ceiling wall 523 reflects the light emitted from the light source 53 at the angle toward the outer side of the light guide plate 70 to the inside of the container 52. The light reflected to the inside of the container 52 is finally directed to the one side surface of the light guide plate 70. The light source device 40 thereby improves the incidence efficiency to the light guide plate 70. Therefore, the amount of the light emitted from the light guide plate 70 to the liquid crystal panel 20 is increased and the brightness on the screen 21 is thus increased.

In the light source device 40, the container 52 has an elongated shape along one direction, and the reflection side wall 522 has an arc shaped or elliptical arc shaped cross section along the one direction.

The reflection side wall 522 has an arc shape or elliptical arc shape bending outward protrudingly. The focus corresponding to the inner surface of the reflection side wall 522 is positioned on the plane that passes through the center of the light guide plate 70 and is substantially parallel with the one surface of the light guide plate 70 that irradiates the liquid crystal panel 20 with light. By adjusting the shape of the inner surface of the reflection side wall 522 as well as the size and the position of the reflection ceiling wall 523 and the reflection plate 55, the diameter of the entering light spot can be made smaller, and the light guide plate 70 included in the lighting device can be replaced by a thinner one. Therefore, the manufacturing cost of the light guide plate 70 can be reduced.

Even when the light guide plate 70 before expansion is positioned farthest from the light source device 40, the diameter of the entering light spot can be made equal to or smaller than the width of the one side surface of the light guide plate 70, by adjusting the shape of the inner surface of the reflection side wall 522 as well as the size and the position of the reflection ceiling wall 523 and the reflection plate 55. Therefore, even when the distance between the light guide plate 70 and the light source device 40 is changed by the thermal expansion or contraction of the light guide plate 70, the light source device 40 does not emit light to the outer side of the light guide plate 70.

In addition, the position of the focal point can be made closer to or farther from the light guide plate 70, by adjusting the shape of the reflection side wall 522. Therefore, the incidence angle on the light guide plate 70 can be adjusted to be the angle that causes total reflection inside the light guide plate 70.

In the light source device 40, the reflection plate 55 has a tray shape with an inward concave.

Because the reflection plate 55 has the tray shape with the inward concave, the reflection plate 55 can reflect the return light from the light guide plate 70 only to the inside of the light guide plate 70, preventing the leakage to the outer side of the light guide plate 70.

The light source device 40 includes a rectangular parallel-piped shaped frame 51 for housing the container 52.

Because the rectangular parallel shaped frame 51 houses the container 52, the intensity of the light from the light source device 40 is increased and attachment of the light source device 40 to another device is facilitated.

In the lighting device, a reflection sheet 76 for reflecting the light that passes through the light guide plate 70 to the inside of the light guide plate is adhered to another side surface of the light guide plate 70 facing the one side surface.

The lighting device can recycle the light that has reached another side surface of the light guide plate 70 from the light source device 40 without leaking the light to the outer side of the light guide plate 70.

The lighting device comprises two of the light source devices 40. Each of the light source devices 40 is arranged to face one side surface of the light guide plate 70 and another side surface facing to the one side surface respectively.

The lighting device with two light source devices 40 can emit more intense light to the rear surface of the liquid crystal panel 20. Therefore, the lighting device can increase the brightness at the screen 21 on the liquid crystal panel 20.

In the lighting device, the polarized light splitting element 78 is a right angle prism having a slant side surface slanting from the inside to the outside of the light guide plate 70 along the direction from the other surface to one surface of the light guide plate 70, and a reflection sheet 75 for reflecting the light emitted to the outside of the light guide plate 70 to the inside is adhered to the other surface of the light guide plate 70 including the polarized light splitting element 78.

According to the lighting device, S-polarized light can be recycled to be directed to the liquid crystal panel 20.

The P-polarized light split by the polarized light splitting element 78 formed as the right angle prism passes through the slant side surface of the right angle prism. On the other hand, the split S-polarized light is reflected on the slant side surface of the right angle prism to the other surface inside the light guide plate 70. The S-polarized light reflected to the other surface of the light guide plate 70 is reflected on the reflection sheet 75, and then reflected on the slant side surface of the right angle prism to the light source device 40. The S-polarized light returned to the light source device 40 is converted into the P-polarized light and redirected to the polarized light splitting element 78. Therefore, the lighting device can recycle the S-polarized light to emit the P-polarized light to the rear surface of the liquid crystal panel 20.

1-5. (canceled)

6. A light source device, comprising:
a container, and
a light source mounted on an inner bottom surface of the container and emitting light toward a ceiling surface of the container,
wherein the container comprises:
a bottom wall,
a reflection side wall arranged around the bottom wall and having an inner surface bulging out, for reflecting light from the light source, and
a reflection ceiling wall arranged protrudingly from a ceiling side edge of the reflection side wall toward the inner circumference, for reflecting light from the light source to the inside of the container, the reflection ceiling wall having an opening for emitting reflected light.

7. The light source device according to claim 6, comprising:
a translucent resin filling inside the container and covering an exterior of the container, and
a reflection plate being smaller than the opening of the reflection ceiling wall and sealed with the translucent resin near the center of the opening, for reflecting light from an inside and an outside of the container.

8. The light source device according to claim 7, wherein one or a plurality of prisms are formed on a surface of the translucent resin through which light emitted from the opening of the reflection ceiling wall passes.

9. A lighting device, comprising:
the light source device according to claim 6, and
a light guide plate having one side surface arranged to face the light source device, for diffusing light emitted from the light source device to inside of the light guide plate through the one side surface to emit the light from one surface of the light guide plate,
wherein
on one end including the one side surface, the light guide plate has a polarized light splitting element for splitting the light emitted from the light source device into P-polarized light and S-polarized light, transmitting the P-polarized light through the polarized light splitting element and reflecting the S-polarized light to an outside of the light guide plate.

10. A liquid crystal display device, comprising:
the lighting device according to claim 9; and
a liquid crystal panel for displaying an image using light emitted from one surface of the light guide plate of the lighting device.
